(19) United States
(12) Patent Application Publication
(10) Pub. No.: US 2025/0140537 A1
(43) Pub. Date: May 1, 2025

(54) CHAMBER AND METHODS FOR DOWNSTREAM RESIDUE MANAGEMENT

(71) Applicant: Applied Materials, Inc., Santa Clara, CA (US)

(72) Inventors: Zaoyuan Ge, San Jose, CA (US); Manjunath Veerappa Chobari Patil, Karnataka (IN); Pavan Kumar S M, Karnataka (IN); Dinesh Babu, Tamilnadu (IN); Nuo Wang, Santa Clara, CA (US); Kaili Yu, Sunnyvale, CA (US); Xinyi Zhong, Santa Clara, CA (US); Bharati Neelamraju, Sunnyvale, CA (US); Liangfa Hu, Newark, CA (US); Neela Ayalasomayajula, Bengaluru (IN); Sungwon Ha, Palo Alto, CA (US); Prashant Kumar Kulshreshtha, San Jose, CA (US); Amit Bansal, Milpitas, CA (US); Daemian Raj Benjamin Raj, Fremont, CA (US); Badri N. Ramamurthi, Los Gatos, CA (US); Travis Mazzy, Fremont, CA (US); Mohammed Salman Mohiuddin, Santa Clara, CA (US); Karthik Suresh Menon, Sunnyvale, CA (US); Lihua Wu, Fremont, CA (US); Prasath Poomani, Tamilnadu (IN)

(73) Assignee: Applied Materials, Inc., Santa Clara, CA (US)

(21) Appl. No.: 18/538,100

(22) Filed: Dec. 13, 2023

(30) Foreign Application Priority Data
Oct. 31, 2023 (IN) 202341074084

(51) Int. Cl. H01J 37/32; B08B 5/00; B08B 9/00

(52) U.S. Cl. CPC H01J 37/32862; B08B 5/00; B08B 9/00; H01J 37/32449

(57) ABSTRACT

Semiconductor processing chambers and systems, as well as methods of cleaning such chambers and systems are provided. Processing chambers and systems include a chamber body that defines a processing region, a liner positioned within the chamber body that defines a liner volume, a faceplate positioned atop the liner, a substrate support disposed within the chamber body, and a cleaning gas source coupled with the liner volume through a cleaning gas plenum and one or more inlet apertures. Systems and chambers include where at least one of the one or more inlet apertures is disposed in the processing region between the faceplate and a bottom wall of the chamber body.

### TECHNICAL FIELD

The present technology relates to semiconductor processes and equipment. More specifically, the present technology relates to substrate processing systems and components.

### BACKGROUND

Integrated circuits are made possible by processes which produce intricately patterned material layers on substrate surfaces. Producing patterned material on a substrate requires controlled methods for forming and removing material. Chamber components often deliver processing gases to a substrate for depositing films or removing materials. To promote symmetry and uniformity, some chambers include remote plasma sources in order to generate higher power plasmas without damaging substrates. However, such plasma sources are generally located upstream of a showerhead and/or blocking plate, limiting the plasma radicals that reach the chamber.

Thus, there is a need for improved systems and methods that can be used to efficiently clean downstream portions of a semiconductor chamber. These and other needs are addressed by the present technology.

### SUMMARY

The present technology is generally directed to substrate processing systems and methods of processing semiconductor substrates. Processing systems include a chamber body that defines a processing region, a liner positioned within the chamber body defining a liner volume, a faceplate positioned atop the liner, and a substrate support disposed within the chamber body. Systems include a cleaning gas source coupled with the liner volume through a cleaning gas plenum and one or more inlet apertures. Systems include where at least one of the one or more inlet apertures is disposed in the processing region between the faceplate and a bottom wall of the chamber body.

In embodiments, systems include where the cleaning gas source is positioned vertically below the chamber body. In more embodiments, the one or more inlet apertures extend through a sidewall of the chamber body. Furthermore, in embodiments, the liner includes an exterior liner portion and an interior liner portion, where the liner volume is defined between the exterior liner portion and the interior liner portion. Additionally or alternatively, embodiments include where the exterior liner portion extends around an interior perimeter of the chamber body. Moreover, in embodiments, the interior liner portion is laterally spaced apart in a direction towards the substrate support from the exterior liner portion. In embodiments, the one or more inlet apertures extend through the exterior liner portion. In yet further embodiments, the one or more inlet apertures extend through the sidewall of the chamber body at a height that is about 10% to about 90% of a total height of the sidewall. In embodiments, systems include an exhaust outlet, where the exhaust outlet is disposed within the liner volume.

The present technology is also generally directed to substrate processing systems. Systems include a chamber having a chamber body that defines a processing region, a liner positioned with the chamber body defining a liner volume, a faceplate positioned atop the liner, and a substrate support disposed within the chamber body. Systems include a cleaning gas source disposed below the chamber body and coupled with the liner volume through one or more inlet apertures in the chamber body. Systems include where at least one of the one or more inlet apertures is disposed in the processing region. Systems include a support frame, where the cleaning gas source is seated on the support frame and the support frame is pivotally mounted to a lateral side of the chamber body.

In embodiments, systems include where the support frame includes a bottom surface having a first plate and a second plate, where one or more tension components support the second plate over the first plate. In more embodiments, at least one of the one or more tension components includes a spring affixed to the first plate. Furthermore, in embodiments, processing systems include two or more chambers, where the cleaning gas source is fluidly coupled with each chamber of the two or more chambers. In yet more embodiments, the cleaning gas source includes a processing position, where the cleaning gas source is disposed along a central axis of the chamber. Additionally or alternatively, in embodiments, systems include one or more secondary mounting plates affixed to a lateral side of the chamber body between the central axis of the chamber and a lateral edge of the chamber. In more embodiments, the one or more secondary mounting plates are configured to receive the cleaning gas source in a second position.

The present technology is also generally directed to semiconductor processing methods. Methods include flowing a cleaning gas or a plasma precursor into a processing region of a semiconductor processing chamber through a showerhead. Methods include where the semiconductor processing chamber contains a liner positioned with processing region defining a liner volume, and a cleaning gas source directly coupled with the liner volume through a cleaning gas plenum and one or more inlet apertures. Methods include where at least one of the one or more inlet apertures is disposed in the processing region. Methods include flowing a second cleaning gas through the one or more inlet apertures and exhausting the second cleaning gas through the liner volume.

In embodiments, methods include where the cleaning gas is flowed into the processing region, and the second cleaning gas is flowed into the semiconductor processing chamber simultaneously with the cleaning gas. In more embodiments, the plasma precursor is flowed into the processing region, wherein the second cleaning gas is flowed into the semiconductor processing chamber simultaneously with the plasma precursor. Moreover, in embodiments, the plasma precursor includes a carbon containing precursor.

Such technology may provide numerous benefits over conventional systems and techniques. For example, the processing systems may provide standalone cleaning capabilities that can reduce residues in downstream locations. Additionally, such processes may be utilized in conjunction with existing clean operations, allowing for enhanced cleaning alone or in conjunction with reduced cleaning gas utilization. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic top plan view of an exemplary processing system according to embodiments of the present technology.

FIG. 2 shows a schematic isometric view of a transfer region of an exemplary chamber system according to embodiments of the present technology.

FIG. 3 shows a partial isometric view of a chamber system according to embodiments of the present technology.

FIG. 4 shows a schematic partial cross-sectional view of an exemplary chamber system according to embodiments of the present technology.

FIG. 5 shows a schematic partial cross-sectional view of an exemplary chamber system according to embodiments of the present technology.

FIG. 6 shows a schematic view of an exemplary chamber system according to some embodiments of the present technology.

FIG. 7 shows schematic partial cross-sectional view of an exemplary chamber system according to embodiments of the present technology.

FIG. 8A shows a top-down schematic view of an exemplary chamber system according to embodiments of the present technology.

FIG. 8B shows a chamber system according to embodiments of the present technology.

FIG. 8C shows a chamber system according to embodiments of the present technology with a cleaning remote plasma source in a chamber access position.

FIG. 9 shows operations of an exemplary method of processing a substrate according to some embodiments of the present technology.

Several of the figures are included as schematics. It is to be understood that the figures are for illustrative purposes, and are not to be considered of scale or proportion unless specifically stated to be of scale or proportion. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Particle contamination within semiconductor chambers is typically controlled by periodically cleaning the chamber using cleaning gases, such as fluorinated or oxygenated compounds, which are excited to inductively or capacitively coupled plasmas. Cleaning gases are selected based on their ability to bind the precursor gases and the deposition material, which has formed on the chamber components, or remain in the chamber processing volume, in order to form stable volatile products which can be exhausted from the chamber, thus cleaning the process environment. However, these existing cleaning solutions require purging of the entire chamber between processes, utilizing large volumes of cleaning gas and allowing large amounts of deposits to form between cleanings.

Moreover, existing plasma cleaning gasses are generated upstream from the processing chamber. Such cleaning devices and methods therefore flow cleaning gasses through one or more components, such as faceplates and blocker plates in order to reach the processing region. Due to the orientation of the plasma source upstream from the processing region, existing cleaning processes often fail to clean around the pumping liner and exhaust, as well the underside of the faceplate. Namely, due to the length of the flow path as well as the large area of exposed surface on faceplates, a majority of the generated radicals recombine as the cleaning gas is flowed into the chamber. Therefore, current cleaning methods often fail to adequately clean the underside of the faceplate (e.g. the processing region facing surface), pumping liner, isolator and exhaust valve, as examples only, which may be referred to as chamber components herein.

In order to clean a chamber that has become fouled, which is a frequent occurrence when utilizing carbon based precursors that exhibit a high risk of component fouling, the chamber must be cooled to a temperature where the cleaning gas will not interact with the chamber components. As may be apparent, such a process requires removing the chamber from processing for an extended amount of time. After the chamber has been cooled and sufficiently cleaned of the process gases and the cleaning by-products have been exhausted out of the chamber, a season process is performed to deposit a film onto components of the chamber forming the processing volume to seal remaining contaminants therein and reduce the contamination level during processing. This process is typically carried out by depositing a season film to coat the interior surfaces forming the processing volume of the chamber. Such a process therefore requires a significant amount of down time as well as product usage.

The present technology has overcome these and other problems by fluidly connecting a standalone cleaning gas source (such as a remote plasma source “RPS”) to one or more chambers via a modified pumping liner. The modified pumping liner may contain an inlet in a lower region of the processing region of the chamber (e.g. below the faceplate). By utilizing such an arrangement, the cleaning gas generated by the additional cleaning gas source (e.g. in addition to a RPS utilized for conventional cleaning or to provide process precursors) is able to contact one or more chamber components below the showerhead, such as the pumping liner, underside of the shower head, and the exhaust lines and valves, as examples only, without having to first pass through a showerhead or blocker plate. Furthermore, due to the unique location of the cleaning gas source and the pumping liner outlet, the RPS may be mounted under the chamber(s), and therefore not require an expansion of the footprint of the system while also providing a desirably short flow path. The modified pumping liner fluidly connected to an additional standalone cleaning gas source may also allow an additional cleaning gas to be generated and flowed during traditional cleaning processes or during deposition processes, reducing the volume of cleaning gas needed to clean the chamber and components therein. Thus, the additional cleaning gas source and unique orientation of the pumping liner discussed herein may allow the cleaning gas to react with residues, during or after processing, forming a gaseous exhaust that does not fowl component parts.

Although the remaining disclosure will routinely identify specific structures, such as four-position chamber systems, for which the present structures and methods may be employed, it will be readily understood that the systems and methods are equally applicable to any number of structures and devices that may benefit from the structural capabilities explained. Accordingly, the technology should not be considered to be so limited as for use with any particular structures alone. Moreover, although an exemplary tool system will be described to provide foundation for the present technology, it is to be understood that the present technology can be incorporated with any number of semiconductor processing chambers and tools that may benefit from some or all of the operations and systems to be described.

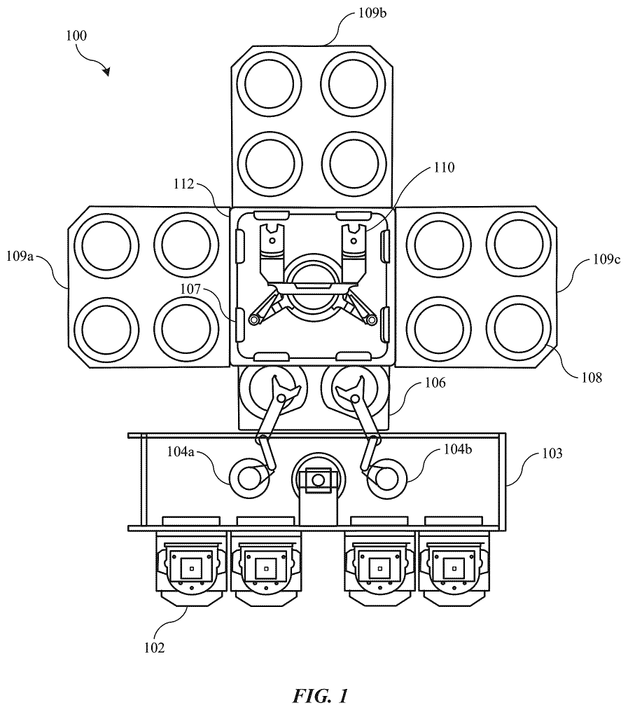

FIG. 1 shows a top plan view of one embodiment of a substrate processing tool or processing system 100 of deposition, etching, baking, and curing chambers according to some embodiments of the present technology. In the figure, a set of front-opening unified pods 102 supply substrates of a variety of sizes that are received within a factory interface 103 by robotic arms 104a and 104b and placed into a load lock or low pressure holding area 106 before being delivered to one of the substrate processing regions 108, positioned in chamber systems or quad sections 109a-c, which may each be a substrate processing system having a transfer region fluidly coupled with a plurality of processing regions 108. Although a quad system is illustrated, it is to be understood that platforms incorporating standalone chambers, twin chambers, and other multiple chamber systems are equally encompassed by the present technology. A second robotic arm 110 housed in a transfer chamber 112 may be used to transport the substrate wafers from the holding area 106 to the quad sections 109 and back, and second robotic arm 110 may be housed in a transfer chamber with which each of the quad sections or processing systems may be connected. Each substrate processing region 108 can be outfitted to perform a number of substrate processing operations including any number of deposition processes including cyclical layer deposition, atomic layer deposition, chemical vapor deposition, physical vapor deposition, as well as etch, pre-clean, anneal, plasma processing, degas, orientation, and other substrate processes.

Each quad section 109 may include a transfer region that may receive substrates from, and deliver substrates to, second robotic arm 110. The transfer region of the chamber system may be aligned with the transfer chamber having the second robotic arm 110. In some embodiments the transfer region may be laterally accessible to the robot. In subsequent operations, components of the transfer sections may vertically translate the substrates into the overlying processing regions 108. Similarly, the transfer regions may also be operable to rotate substrates between positions within each transfer region. The substrate processing regions 108 may include any number of system components for depositing, annealing, curing and/or etching a material film on the substrate or wafer. In one configuration, two sets of the processing regions, such as the processing regions in quad section 109a and 109b, may be used to deposit material on the substrate, and the third set of processing chambers, such as the processing chambers or regions in quad section 109c, may be used to cure, anneal, or treat the deposited films. In another configuration, all three sets of chambers, such as all twelve chambers illustrated, may be configured to both deposit and/or cure a film on the substrate.

As illustrated in the figure, second robotic arm 110 may include two arms for delivering and/or retrieving multiple substrates simultaneously. For example, each quad section 109 may include two accesses 107 along a surface of a housing of the transfer region, which may be laterally aligned with the second robotic arm. The accesses may be defined along a surface adjacent the transfer chamber 112. In some embodiments, such as illustrated, the first access may be aligned with a first substrate support of the plurality of substrate supports of a quad section. Additionally, the second access may be aligned with a second substrate support of the plurality of substrate supports of the quad section. The first substrate support may be adjacent to the second substrate support, and the two substrate supports may define a first row of substrate supports in some embodiments. As shown in the illustrated configuration, a second row of substrate supports may be positioned behind the first row of substrate supports laterally outward from the transfer chamber 112. The two arms of the second robotic arm 110 may be spaced to allow the two arms to simultaneously enter a quad section or chamber system to deliver or retrieve one or two substrates to substrate supports within the transfer region.

Any one or more of the transfer regions described may be incorporated with additional chambers separated from the fabrication system shown in different embodiments. It will be appreciated that additional configurations of deposition, etching, annealing, and curing chambers for material films are contemplated by processing system 100. Additionally, any number of other processing systems may be utilized with the present technology, which may incorporate transfer systems for performing any of the specific operations, such as the substrate movement. In some embodiments, processing systems that may provide access to multiple processing chamber regions while maintaining a vacuum environment in various sections, such as the noted holding and transfer areas, may allow operations to be performed in multiple chambers while maintaining a particular vacuum environment between discrete processes.

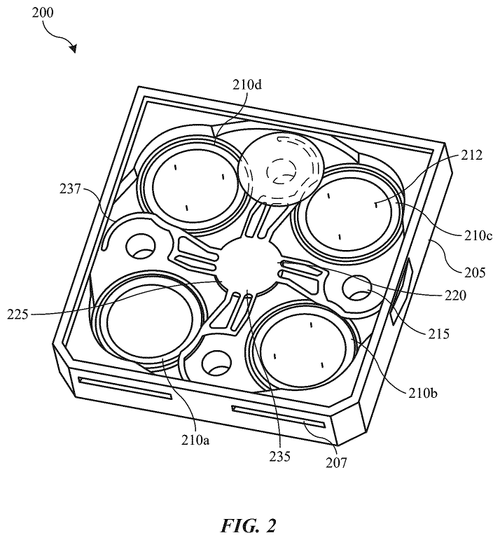

As noted, processing system 100, or more specifically quad sections or chamber systems incorporated with processing system 100 or other processing systems, may include transfer sections positioned below the processing chamber regions illustrated. FIG. 2 shows a schematic isometric view of a transfer section of an exemplary chamber system 200 according to some embodiments of the present technology. FIG. 2 may illustrate additional aspects or variations of aspects of the transfer region described above, and may include any of the components or characteristics described. The system illustrated may include a transfer region housing 205, which may be a chamber body as discussed further below, defining a transfer region in which a number of components may be included. The transfer region may additionally be at least partially defined from above by processing chambers or processing regions fluidly coupled with the transfer region, such as processing chamber regions 108 illustrated in quad sections 109 of FIG. 1. A sidewall of the transfer region housing may define one or more access locations 207 through which substrates may be delivered and retrieved, such as by second robotic arm 110 as discussed above. Access locations 207 may be slit valves or other sealable access positions, which include doors or other sealing mechanisms to provide a hermetic environment within transfer region housing 205 in some embodiments. Although illustrated with two such access locations 207, it is to be understood that in some embodiments only a single access location 207 may be included, as well as access locations on multiple sides of the transfer region housing. It is also to be understood that the transfer section illustrated may be sized to accommodate any substrate size, including 200 mm, 300 mm, 450 mm, or larger or smaller substrates, including substrates characterized by any number of geometries or shapes.

Within transfer region housing 205 may be a plurality of substrate supports 210 positioned about the transfer region volume. Although four substrate supports are illustrated, it is to be understood that any number of substrate supports are similarly encompassed by embodiments of the present technology. For example, greater than or about three, four, five, six, eight, or more substrate supports 210 may be accommodated in transfer regions according to embodiments of the present technology. Second robotic arm 110 may deliver a substrate to either or both of substrate supports 210a or 210b through the accesses 207. Similarly, second robotic arm 110 may retrieve substrates from these locations. Lift pins 212 may protrude from the substrate supports 210, and may allow the robot to access beneath the substrates. The lift pins may be fixed on the substrate supports, or at a location where the substrate supports may recess below, or the lift pins may additionally be raised or lowered through the substrate supports in some embodiments. Substrate supports 210 may be vertically translatable, and in some embodiments may extend up to processing chamber regions of the substrate processing systems, such as processing chamber regions 108, positioned above the transfer region housing 205.

The transfer region housing 205 may provide access 215 for alignment systems, which may include an aligner that can extend through an aperture of the transfer region housing as illustrated and may operate in conjunction with a laser, camera, or other monitoring device protruding or transmitting through an adjacent aperture, and that may determine whether a substrate being translated is properly aligned. Transfer region housing 205 may also include a transfer apparatus 220 that may be operated in a number of ways to position substrates and move substrates between the various substrate supports. In one example, transfer apparatus 220 may move substrates on substrate supports 210a and 210b to substrate supports 210c and 210d, which may allow additional substrates to be delivered into the transfer chamber. Additional transfer operations may include rotating substrates between substrate supports for additional processing in overlying processing regions.

Transfer apparatus 220 may include a central hub 225 that may include one or more shafts extending into the transfer chamber. Coupled with the shaft may be an end effector 235. End effector 235 may include a plurality of arms 237 extending radially or laterally outward from the central hub. Although illustrated with a central body from which the arms extend, the end effector may additionally include separate arms that are each coupled with the shaft or central hub in various embodiments. Any number of arms may be included in embodiments of the present technology. In some embodiments a number of arms 237 may be similar or equal to the number of substrate supports 210 included in the chamber. Hence, as illustrated, for four substrate supports, transfer apparatus 220 may include four arms extending from the end effector. The arms may be characterized by any number of shapes and profiles, such as straight profiles or arcuate profiles, as well as including any number of distal profiles including hooks, rings, forks, or other designs for supporting a substrate and/or providing access to a substrate, such as for alignment or engagement.

The end effector 235, or components or portions of the end effector, may be used to contact substrates during transfer or movement. These components as well as the end effector may be made from or include a number of materials including conductive and/or insulative materials. The materials may be coated or plated in some embodiments to withstand contact with precursors or other chemicals that may pass into the transfer chamber from an overlying processing chamber.

Additionally, the materials may be provided or selected to withstand other environmental characteristics, such as temperature. In some embodiments, the substrate supports may be operable to heat a substrate disposed on the support. The substrate supports may be configured to increase a surface or substrate temperature to temperatures greater than or about 100° C., greater than or about 200° C., greater than or about 300° C., greater than or about 400° C., greater than or about 500° C., greater than or about 600° C., greater than or about 700° C., greater than or about 800° C., or higher. Any of these temperatures may be maintained during operations, and thus components of the transfer apparatus 220 may be exposed to any of these stated or encompassed temperatures. Consequently, in some embodiments any of the materials may be selected to accommodate these temperature regimes, and may include materials such as ceramics and metals that may be characterized by relatively low coefficients of thermal expansion, or other beneficial characteristics.

Component couplings may also be adapted for operation in high temperature and/or corrosive environments. For example, where end effectors and end portions are each ceramic, the coupling may include press fittings, snap fittings, or other fittings that may not include additional materials, such as bolts, which may expand and contract with temperature, and may cause cracking in the ceramics. In some embodiments the end portions may be continuous with the end effectors, and may be monolithically formed with the end effectors. Any number of other materials may be utilized that may facilitate operation or resistance during operation, and are similarly encompassed by the present technology. The transfer apparatus 220 may include a number of components and configurations that may facilitate the movement of the end effector in multiple directions, which may facilitate rotational movement, as well as vertical movement, or lateral movement in one or more ways with the drive system components to which the end effector may be coupled.

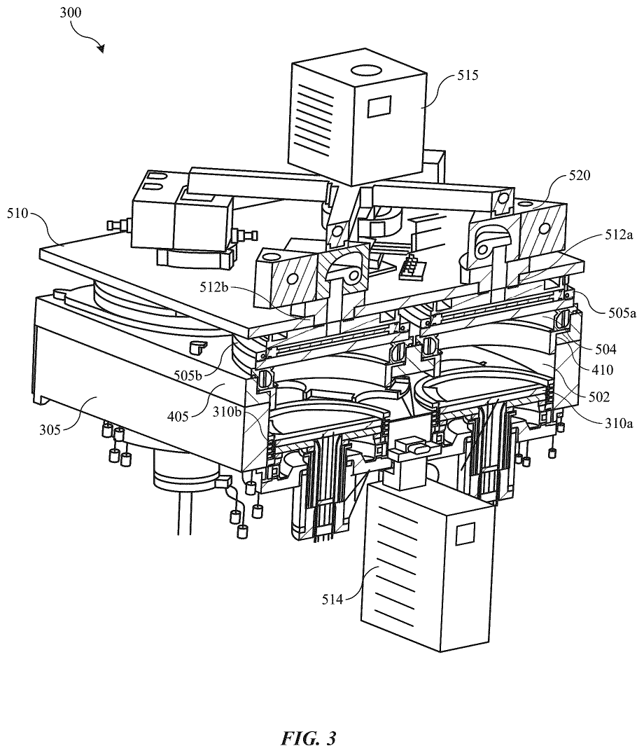

FIG. 3 shows a schematic partial isometric view of chamber system 300 according to some embodiments of the present technology. The figure may illustrate a partial cross-section through two processing regions and a portion of a transfer region of the chamber system. For example, chamber system 300 may be a quad section of processing system 100 described previously, and may include any of the components of any of the previously described components or systems.

Chamber system 300, as developed through the figure, may include a chamber body 305 defining a transfer region 502 including substrate supports 310, which may extend into the chamber body 305 and be vertically translatable as previously described. First lid plate 405 may be seated overlying the chamber body 305, and may define apertures 410 producing access for processing region 504 to be formed with additional chamber system components. Seated about or at least partially within each aperture may be a lid stack 505, and chamber system 300 may include a plurality of lid stacks 505, including a number of lid stacks equal to a number of apertures 410 of the plurality of apertures. Each lid stack 505 may be seated on the first lid plate 405, and may be seated on a shelf produced by recessed ledges through the second surface of the first lid plate. The lid stacks 505 may at least partially define processing regions 504 of the chamber system 300.

As illustrated, processing regions 504 may be vertically offset from the transfer region 502, but may be fluidly coupled with the transfer region. Additionally, the processing regions may be separated from the other processing regions. Although the processing regions may be fluidly coupled with other processing regions through the transfer region from below, the processing regions may be fluidly isolated, from above, from each of the other processing regions. Each lid stack 505 may also be aligned with a substrate support in some embodiments. For example, as illustrated, lid stack 505a may be aligned over substrate support 310a, and lid stack 505b may be aligned over substrate support 310b. When raised to operational positions, such as a second position, the substrates may deliver substrates for individual processing within the separate processing regions. When in this position, as will be described further below, each processing region 504 may be at least partially defined from below by an associated substrate support in the second position.

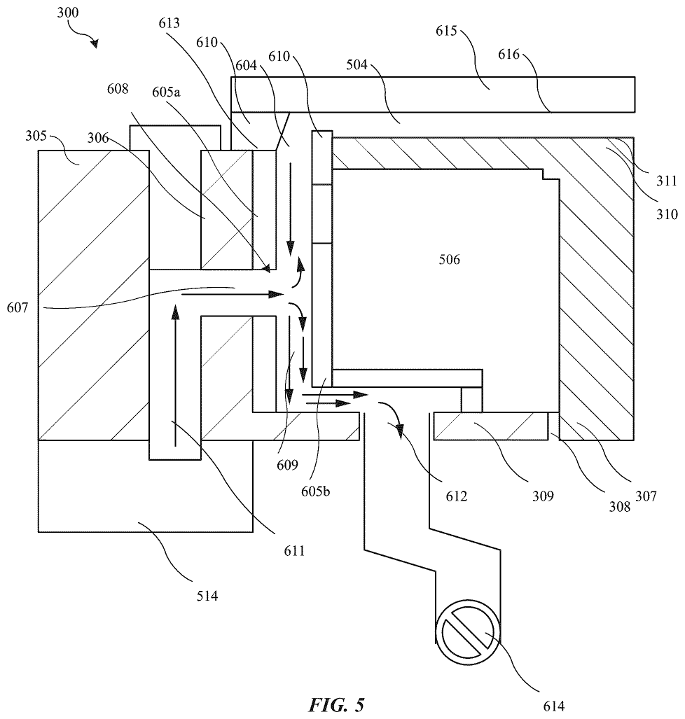

FIG. 3 also illustrates embodiments in which a second lid plate 510 may be included for the chamber system. Second lid plate 510 may be coupled with each of the lid stacks, which may be positioned between the first lid plate 405 and the second lid plate 510 in some embodiments. As will be explained below, the second lid plate 510 may facilitate accessing components of the lid stacks 505. Second lid plate 510 may define a plurality of apertures 512 through the second lid plate. Each aperture of the plurality of apertures may be defined to provide fluid access to a specific lid stack 505 or processing region 504. A remote plasma unit 515 may optionally be included in chamber system 300 in some embodiments, and may be supported on second lid plate 510. Moreover, as will be discussed in greater detail below, embodiments according to the present technology include a cleaning gas source 514, which may be an RPS, that is separate from the remote plasma unit 515 discussed above. In embodiments, the cleaning gas source 514 may be mounted below processing region 504 and may be fluidly connected with the processing region 504 at a position below lid stack 505 (discussed in greater detail in FIGS. 5-8C).

In some embodiments, remote plasma unit 515 may be fluidly coupled with each aperture 512 of the plurality of apertures through second lid plate 510. Isolation valves 520 may be included along each fluid line to provide fluid control to each individual processing region 504. For example, as illustrated, aperture 512a may provide fluid access to lid stack 505a. Aperture 512a may also be axially aligned with any of the lid stack components, as well as with substrate support 310a in some embodiments, which may produce an axial alignment for each of the components associated with individual processing regions, such as along a central axis through the substrate support or any of the components associated with a particular processing region 504. Similarly, aperture 512b may provide fluid access to lid stack 505b, and may be aligned, including axially aligned with components of the lid stack as well as substrate support 310b in some embodiments.

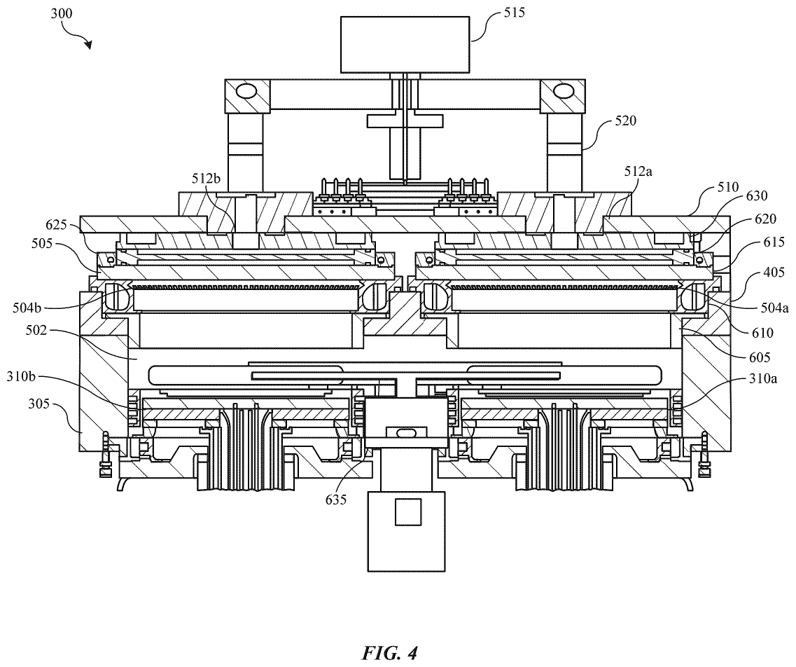

FIG. 4 shows a schematic cross-sectional elevation view of one embodiment of chamber system 300 according to some embodiments of the present technology. FIG. 4 may illustrate the cross-sectional view shown above in FIG. 3, and may further illustrate components of the system. The figure may include components of any of the systems illustrated and described previously, and may also show further aspects of any of the previously described systems. It is to be understood that the illustration may also show exemplary components as would be seen through any two adjacent processing regions 108 in any quad section 109 described above. However, while not shown, it should be understood that, in embodiments, the components discussed herein may be applicable to chambers having more or less than four sections, such as single chamber sections, double chamber sections, or others as known in the art.

The elevation view may illustrate the configuration or fluid coupling of one or more processing regions 504 with a transfer region 502. For example, a continuous transfer region 502 may be defined by chamber body 305. The housing may define an open interior volume in which a number of substrate supports 310 may be disposed. For example, as illustrated in FIG. 1, exemplary processing systems may include four or more, including a plurality of substrate supports 310 distributed within the chamber body about the transfer region. The substrate supports may be pedestals as illustrated, although a number of other configurations may also be used. In some embodiments the pedestals may be vertically translatable between the transfer region 502 and the processing regions 504 overlying the transfer region. The substrate supports may be vertically translatable along a central axis of the substrate support along a path between a first position and a second position within the chamber system. Accordingly, in some embodiments each substrate support 310 may be axially aligned with an overlying processing region 504 defined by one or more chamber components.

The open transfer region may afford the ability of a transfer apparatus 635, such as a carousel, to engage and move substrates, such as rotationally, between the various substrate supports. The transfer apparatus 635 may be rotatable about a central axis. This may allow substrates to be positioned for processing within any of the processing regions 504 within the processing system. The transfer apparatus 635 may include one or more end effectors that may engage substrates from above, below, or may engage exterior edges of the substrates for movement about the substrate supports. The transfer apparatus may receive substrates from a transfer chamber robot, such as robot 110 described previously. The transfer apparatus may then rotate substrates to alternate substrate supports to facilitate delivery of additional substrates.

Once positioned and awaiting processing, the transfer apparatus may position the end effectors or arms between substrate supports, which may allow the substrate supports to be raised past the transfer apparatus 635 and deliver the substrates into the processing regions 504, which may be vertically offset from the transfer region 502. For example, and as illustrated, substrate support 310a may deliver a substrate into processing region 504a, while substrate support 310b may deliver a substrate into processing region 504b. This may occur with the other two substrate supports and processing regions, as well as with additional substrate supports and processing regions in embodiments for which additional processing regions are included. In this configuration, the substrate supports may at least partially define a processing region 504 from below when operationally engaged for processing substrates, such as in the second position, and the processing regions may be axially aligned with an associated substrate support. The processing regions may be defined from above by the components of the lid stacks 505, which may each include one or more of the illustrated components. In some embodiments, each processing region may have individual lid stack components, although in some embodiments components may accommodate multiple processing regions 504. Based on this configuration, in some embodiments each processing region 504 may be fluidly coupled with the transfer region, while being fluidly isolated from above from each other processing region within the chamber system or quad section.

The lid stack 505 may include a number of components, which may facilitate flow of precursors through the chamber system, and may be at least partially contained between the first lid plate 405 and the second lid plate 510. A liner 605 may be seated directly on the shelf formed by each recessed ledge in first lid plate 405. For example, liner 605 may define a lip or flange, which may allow liner 605 to extend from the shelf of first lid plate 405. Liner 605, alone or in combination with pumping liner 610 may extend vertically below the first surface of first lid plate 405 as will be discussed in greater detail below, and may at least partially extend into the open transfer region 502. The liner 605 may be made of materials similar or different from the chamber body materials, and may be or include materials that limit deposition or retention of materials on the surface of liner 605. Liner 605 may define an access diameter for substrate support 310, and may be characterized by any of the gap amounts described above for clearance between the substrate support 310 and the liner 605 when included.

Seated on the liner 605 may be a pumping liner 610, which may at least partially extend within the recess or along the recessed ledge defined in the second surface of first lid plate 405. In some embodiments, pumping liner 610 may be seated on liner 605 on the shelf formed by the recessed ledge. Pumping liner 610 may be an annular component, and may at least partially define the processing region 504 radially, or laterally depending on the volume geometry. The pumping liner may define an exhaust plenum within the liner, which may define a plurality of apertures on an inner annular surface of the pumping liner providing access to the exhaust plenum. The exhaust plenum may at least partially extend vertically above a height of the first lid plate 405, which may facilitate delivering exhausted materials through an exhaust channel formed through the first lid plate and chamber body as previously described. However, in embodiments, as will be discussed in greater detail below, all or a portion of the exhaust may exit through an exhaust port in a bottom surface of the chamber body 305. A portion of the pumping liner may at least partially extend across the second surface of the first lid plate 405 to complete the exhaust channel between the exhaust plenum of the pumping liner, and the channel formed through the chamber body and first lid plate.

A faceplate 615 may be seated on the pumping liner 610, and may define a plurality of apertures through the faceplate 615 for delivering precursors into the processing region 504. Faceplate 615 may at least partially define an associated processing region 504 from above, which may at least partially cooperate with the pumping liner and substrate support in a raised position to generally define the processing region. Faceplate 615 may operate as an electrode of the system for producing a local plasma within the processing region 504, and thus in some embodiments, faceplate 615 may be coupled with an electrical source or may be grounded. In some embodiments the substrate support 310 may operate as the companion electrode for generating a capacitively-coupled plasma between the faceplate and the substrate support.

A blocker plate 620 may be seated on the faceplate 615, which may further distribute processing fluids or precursors to produce a more uniform flow distribution to a substrate. Blocker plate 620 may also define a number of apertures through the plate. In some embodiments the blocker plate 620 may be characterized by a diameter less than a diameter of the faceplate as illustrated, which may provide an annular access on the surface of the faceplate radially outward from the blocker plate 620. In some embodiments a faceplate heater 625 may be seated on the annular access, and may contact faceplate 615 to heat the component during processing or other operations. In some embodiments, blocker plate 620 and faceplate heater 625 may be characterized together as having an outer radial diameter equal to or substantially equal to an outer radial diameter of faceplate 615. Similarly, faceplate heater 625 may be characterized as having an outer radial diameter equal to or substantially equal to an outer radial diameter of faceplate 615 in some embodiments. Faceplate heater 625 may extend about blocker plate 620, and may or may not directly contact blocker plate 620 on an outer radial edge of the blocker plate 620.

A gas box 630 may be positioned above the blocker plate 620, and the gas box 630 of each of the lid stacks 505 may at least partially support the second lid plate 510. Gas box 630 may define a central aperture that is aligned with an associated aperture 512 of the plurality of apertures defined through second lid plate 510. Second lid plate 510 may support a remote plasma unit 515 in some embodiments, which may include piping to each of the apertures 512, and into each processing region 504. Adapters may be positioned through apertures 512 to couple the remote plasma unit piping to the gas boxes 630. Additionally, isolation valves 520 may be positioned within the piping to meter flow to each individual processing region 504 in some embodiments.

O-rings or gaskets may be seated between each component of the lid stack 505, which may facilitate vacuum processing within chamber system 300 in some embodiments. The specific component coupling between the first lid plate 405 and the second lid plate 510 may occur in any number of ways, which may facilitate accessing system components. For example, a first set of couplings may be incorporated between the first lid plate 405 and the second lid plate 510, which may facilitate removal of both lid plates and each lid stack 505, which may provide access to the substrate supports or transfer apparatus within the transfer region of the chamber system. These couplings may include any number of physical and removable couplings extending between the two lid plates, which may allow them to be separated from the chamber body 305 as a whole. For example, a drive motor on a mainframe containing the chamber system 300 may be removably coupled with the second lid plate 510, which may lift the components away from the chamber body 305.

When the couplings between the first lid plate 405 and second lid plate 510 are disengaged, second lid plate 510 may be removed while first lid plate 405 may remain on chamber body 305, which may facilitate access to one or more components of the lid stacks 505. The break within the lid stack 505 may occur between any two components described previously, some of which may be coupled with first lid plate 405, and some of which may be coupled with second lid plate 510. For example, in some embodiments each of the gas boxes 630 may be coupled with second lid plate 510. Thus, when the second lid plate is lifted from the chamber system, the gas boxes may be removed, providing access to the blocker plate and faceplate. Continuing this example, the blocker plate 620 and faceplate 615 may or may not be coupled with the first lid plate 405. For example, although mechanical coupling may be included, the components may be decoupled and sit floating on the first lid plate 405, such as with locating features maintaining proper alignment of the components. It is to be understood that the example is intended to be non-limiting, and illustrative of any number of break configurations between any two components of the lid stack when the second lid plate 510 is separated from the first lid plate 405. Consequently, depending on the coupling between the first lid plate and second lid plate, the entire lid stack and both lid plates may be removed providing access to the transfer region, or the second lid plate may be removed providing access to the lid stack components.

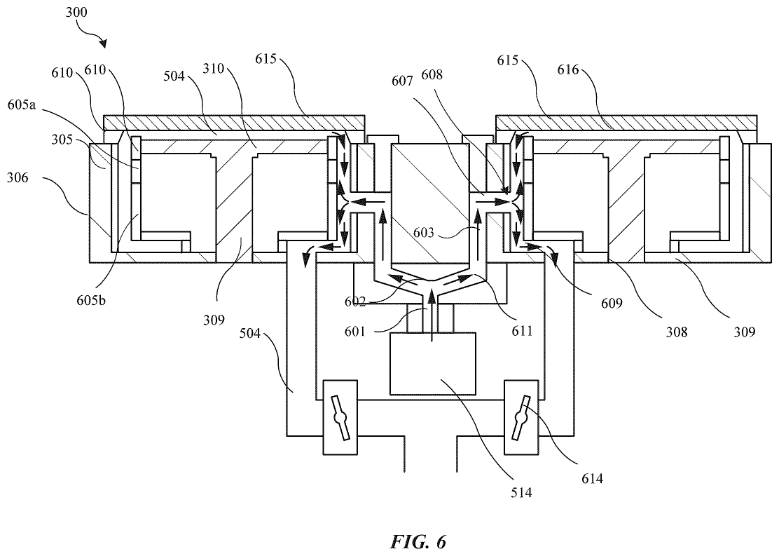

Referring next to FIGS. 5 and 6, a partial cross-sectional view of a chamber system 300 according to embodiments of the present technology. FIGS. 5 and 6 may illustrate the cross-sectional view shown above in FIGS. 3 and/or 4, and may further illustrate components of the system. The figure may include components of any of the systems illustrated and described previously, and may also show further aspects of any of the previously described systems. As illustrated, the cleaning gas source 514 may be directly connected to a liner volume 609 of chamber 300 via one or more inlet apertures 608 disposed vertically below faceplate 615. As discussed above, by utilizing such an arrangement, the cleaning gas source 514, which may also include a separate remote plasmas source (RPS), as well as any other cleaning gas source, may directly clean chamber components without first traversing faceplate 615.

Namely, in embodiments, liner 605 and/or sidewall 306 may include one or more inlet apertures 608. The inlet aperture 608 is illustrated as being disposed through exterior liner portion 605a and sidewall 306 at a location corresponding to a cleaning gas plenum 607 extending through sidewall 306 of chamber body 305. However, in embodiments, the inlet aperture 608 and cleaning gas plenum 607 may be disposed at any one or more locations below processing region 504 and/or faceplate 615 (e.g. between processing region 504/faceplate 615 and bottom wall 309 of chamber body 305), such as on bottom wall 309. Moreover, while only one inlet aperture 608 is illustrated, in embodiments, the cleaning gas plenum may extend through the chamber sidewall 306 and circumferentially around chamber body 305, with one or more inlet apertures 608 fluidly connecting the cleaning gas plenum to the liner volume 609. Moreover, in embodiments, the one or more inlet apertures 608 may be an opening in the liner 605 that extends circumferentially around all or a portion of the chamber body.

In embodiments, the one or more liners 605 may extend along one or more sidewalls 306 of the chamber body 305 and may contain an exterior portion 605a and an interior portion 605b. In embodiments, exterior portion 605a may extend in a generally vertical direction along the perimeter of one or more sidewalls 306, such as generally around an exterior perimeter of the interior of the chamber body. In such embodiments, the exterior portion 605a may extend from a faceplate 615 to a bottom wall 309, along one or more sidewalls 306. However, in embodiments, such as discussed above, a pumping liner 610 may be disposed above liner 605. Thus, in embodiments where a pumping liner 610 is utilized, the exterior portion 605a may extend from a lower surface of pumping liner 610 to bottom wall 309 of the chamber body 305 (e.g. the pumping liner 610 is disposed between exterior portion 605a and faceplate 615).

Nonetheless, interior portion 605b may be laterally spaced apart from exterior portion 605a in a direction toward processing region 504, defining a liner volume 609 between the exterior portion 605a and interior portion 605b. The interior portion 605b may extend into the processing region 504 as defined above and may define an access diameter for substrate support 310. Thus, in embodiments, interior portion 605b may be spaced apart from exterior portion 605a by any amounts such that the access diameter as discussed above is maintained between interior portion 605a and substrate support 310. In embodiments, the interior portion 605b may extend from a position generally parallel to an upper surface of substrate support 310, such as when substrate support 310 is in a processing position, to a bottom wall 309 of the chamber body 305. However, in embodiments, such as discussed above, a pumping liner 610 may be disposed above liner 605. Thus, in embodiments where a pumping liner 610 is utilized, the pumping liner may be seated on the interior portion 605b, such that the interior portion 605b extends from a lower surface of pumping liner 610 to bottom wall 309 of the chamber body 305. In such embodiments, the pumping liner 610 is seated on interior portion 605a and therefore disposed between interior portion 605b and faceplate 615. However, in embodiments, it should be understood that interior portion 605b and exterior portion 605a may be formed monolithically from a single piece with a hollow interior.

In embodiments, the interior portion 605b may contain one or more laterally extending portions generally orthogonal to the vertically extending portions discussed above. For instance, while an upper end of the interior portion 605b may have a location generally constrained by the substrate support 310, a bottom portion adjacent to bottom wall 309 may extend to incorporate one or more addition features and/or chamber components desired to be cleaned. For instance, in embodiments, interior portion 605b may laterally extend towards a purge volume 506 such that exhaust outlet 612 is contained within connected to the liner volume. Moreover, as illustrated, in embodiments, the exhaust outlet 612 may be disposed within the region of the chamber encompassed by the liner volume, allowing enhanced cleaning of the exhaust and valves therein.

Furthermore, as illustrated, the top 613 of liner 605 may be open or contain an opening so as to be fluidly connected to the processing region. 504. In embodiments, the top 613 of liner 605 may be directly open to the processing region 504, or may be fluidly connected via one or more additional components, such as through pumping liner 610.

Regardless of the orientation, the liner 605 defines a liner volume 609 that extends around at least a portion of an interior of chamber body 305 and fluidly connects the cleaning gas source 514 with an exhaust outlet 612. As discussed above exhaust outlet 612 may be a sole exhaust outlet for the system or may be a parallel exhaust outlet to an exhaust outlet coupled with the pumping liner plenum discussed above. The exhaust outlet 612 may be in fluid connection with an exhaust manifold via one or more valves 614. Surprisingly, due at least in part to the location of the one or more inlet apertures 608 alone or in combination with the short path length between the cleaning gas source 514 and the liner volume 609 and exhaust outlet 612, the processes and systems according to the present technology exhibit improved cleaning of one or more chamber components, such as the exhaust outlet 612, exhaust valve 614, liner(s) 605/610, and a process region facing surface 616 of faceplate 615.

Namely, in embodiments, the one or more inlet apertures 608 and corresponding cleaning gas plenum 607 may be disposed at a location within the chamber body that is between an upper surface 311 of substrate support 310 and bottom wall 309 of the chamber body 305. In embodiments, the cleaning gas plenum 607 and one or more inlet apertures 608 may be formed through sidewall 306 of chamber body 305 at a height that is from about 10% to about 90% of a total height of sidewall 306 (e.g. height formed between bottom wall 309 and lid plate 405), such as from about 15% to about 85%, such as from about 20% to about 80%, such as from about 25% to about 75%, such as from about 30% to about 70%, such as from about 35% to about 65%, such as from about 40% to about 60%, such as from about 45% to about 55%, or any ranges or values therebetween. In such as manner, as illustrated by radical flow path 611, the radicals formed by cleaning gas source 514 may flow through sidewall 306 of chamber body 305 via cleaning gas plenum 607 towards the one or more inlet apertures 608 and into liner volume 609. Thus, the radical flow path 611 may interact around the circumference of the liner volume, the process region facing surface 606 of faceplate 615, and pumping liner 610, as well as exhaust outlet 612 and valve(s) 614, all without traversing through faceplate 615 (such as occurs with a conventional cleaning system upstream of faceplate 615).

As known in the art, radicals, including cleaning gas radicals formed from fluorine and oxygen containing precursors, tend to recombine with other gas particles or contaminants. Therefore, the longer the flow path and the more difficult the path is to traverse, results in less radicals available for cleaning. As discussed above, conventional cleaning systems flow radicals from a position upstream of faceplate 615. Any radicals must therefore pass through the faceplate apertures. As the apertures tend to be quite small, there is a large surface area for the radicals to interact with, leading to a high percentage of the radicals recombining with other gas radicals or compounds found on the faceplate. Such a phenomenon leads to a low percentage of radicals remaining in the cleaning gas by the time flow is experienced in the processing region 504 or elsewhere in chamber body 305. Furthermore, existing RPS units, such as unit 515 discussed above, are unable to produce both process precursors and cleaning gasses simultaneously while also adhering to necessary process conditions.

Surprisingly, due at least in part to the lack of necessity of traversing faceplate 615 and the apertures therein, a large percentage of radicals according to the present technology form all or part of the cleaning gas entering the liner volume 609. Moreover, as discussed below, the present technology has found that by mounting or otherwise disposing the cleaning gas source 514 below chamber 300, the radical path length may be formed to be desirably short, while also maintaining the existing footprint of the system. Thus, surprisingly, the processes and systems discussed herein are able to greatly improve the cleaning of processing residues, even with reduced cleaning gas volume.

Furthermore, due to the unique location of the inlet apertures 608 and cleaning gas source 514, and by including a standalone cleaning gas source in addition to a process RPS (such as RPS 515), the cleaning gas generated by the cleaning gas source 514 may be flowed during processing operations as well as conventional clean operations. In such a manner, the cleaning gas generated by the cleaning gas source 514 may interact with processing residues 604 during processing, binding with the processing residues prior to the residue depositing on a surface of the one or more chamber components. Thus, the present technology may not only provide an enhanced clean, but may prevent deposits that drive the necessity for a full clean operation discussed above, which requires significant down time of the system due to the cooling and seasoning of the chamber. Moreover, due at least in part to the unique location of the one or more inlet apertures and cleaning RPS, the cleaning gas generated by the cleaning RPS may be flowed during conventional cleaning operations, reducing the cleaning gas needed to be introduced from upstream of faceplate 615. Such a process greatly reduces the volume of cleaning gas necessary for cleaning, and also significantly reduces the time necessary for cleaning. Thus, the present technology provides for enhanced cleaning operations that utilized a reduced volume of cleaning gas as well as reduced cleaning time.

Nonetheless, in embodiments, it may be desirable to isolate the exhaust outlet 612 from a purge volume 506 to reduce the area for cleaning as well as the necessary volume of cleaning gas from cleaning gas source 514. The purge volume 506 may be generally defined by the substrate support 310, sidewalls 306, and bottom wall 309 when the substrate support 310 is in the processing position. The purge volume 506 may be fluidly connected to a purge gas source via inlet 308.

While FIG. 5 illustrates a single chamber and FIG. 6 illustrates a double chamber, it should be understood that the cleaning gas source 514 may be utilized with more than two chambers, such as four chambers or more, concurrently, as well as any one or more of the chambers discussed above. As illustrated in FIG. 6, in such embodiments, the cleaning gas source 514 may be fluidly connected to two or more chambers 300, forming a radical flow path 611 to each chamber 300. While other structures may be utilized, in embodiments, a radical inlet 601 may be attached to a splitter 602. Splitter 602 may be fixedly or releasably attached to radical inlet 601, such as using one or more clamps, and may contain a number of flow paths equal to the number of connected chambers. Nonetheless, splitter 602 may direct radicals along flow path 611 through one or more connectors 603, into cleaning as plenum 607, and through the one or more inlet apertures 608. Thus, the present technology may be utilized for cleaning multiple chambers simultaneously, in embodiments.

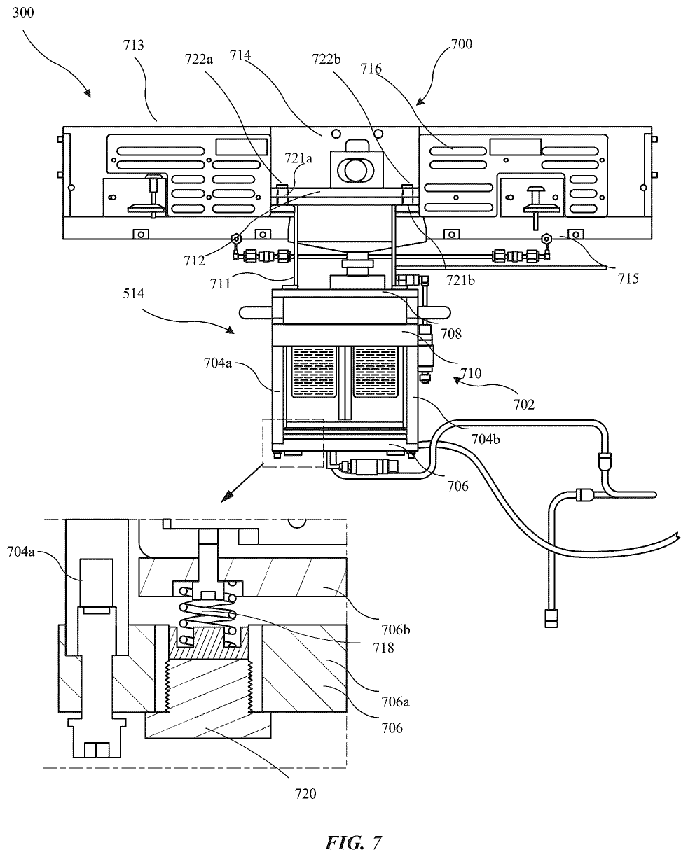

Surprisingly, the present technology has found that by utilizing a tailored mounting bracket, the cleaning gas source 514 (e.g. an additional RPS or cleaning gas source from the plasma and cleaning gas sources discussed above) may be utilized as discussed above without increasing the footprint of current chambers 300 or inhibiting the function of chamber 300. Looking to FIG. 7, cleaning gas source 514 may be attached to chamber 300 via mounting assembly 700. Namely, by utilizing the mounting assembly 700 discussed herein, the cleaning gas source 514 may be disposed vertically below chamber 300 without contacting or damaging the critical components located on a bottom surface of the chamber. By utilizing such a mounting assembly, an additional cleaning gas source may be incorporated into chamber 300 without inhibiting function or increasing the footprint of the system, while also providing adequate support for the cleaning gas source and any changes exhibited therefrom during processing.

In embodiments, mounting assembly 700 may include a support frame 702 having two or more opposed side supports 704a, 704b, a bottom support 706, and an opposed upper support 708. The cleaning gas source 514 may be seated on bottom support 706 and may be laterally supported by the opposed side supports 704a, 704b. In addition, upper support 708 may provide one or more mounting surfaces for support arms 711. In embodiments, it may be desirable to include one or more braces 710, which may connect opposed sides 708a, 704b, and/or opposed bottom and upper supports 706, 708, and which may provide additional support if needed. While the support frame 702 is illustrated as having one or more open sides, it should be clear that, in embodiments, some or all of the cleaning gas source 514 may be contained within a solid housing.

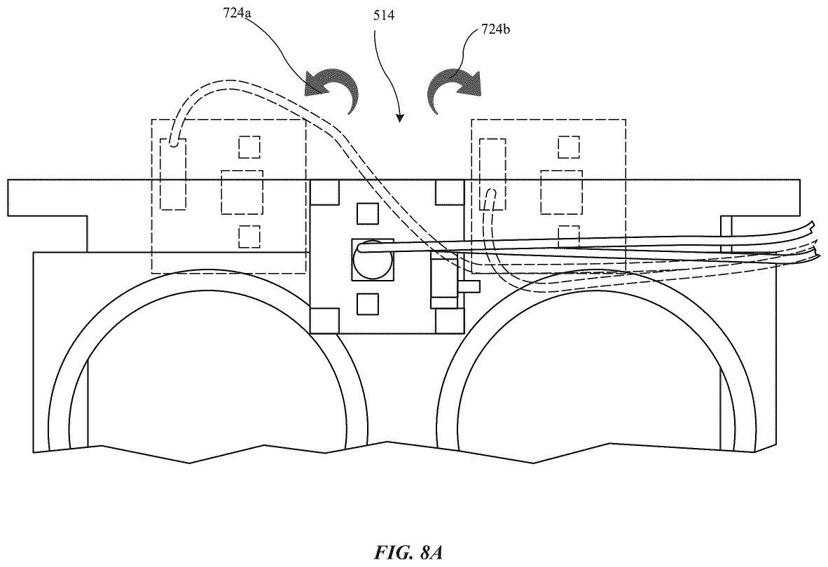

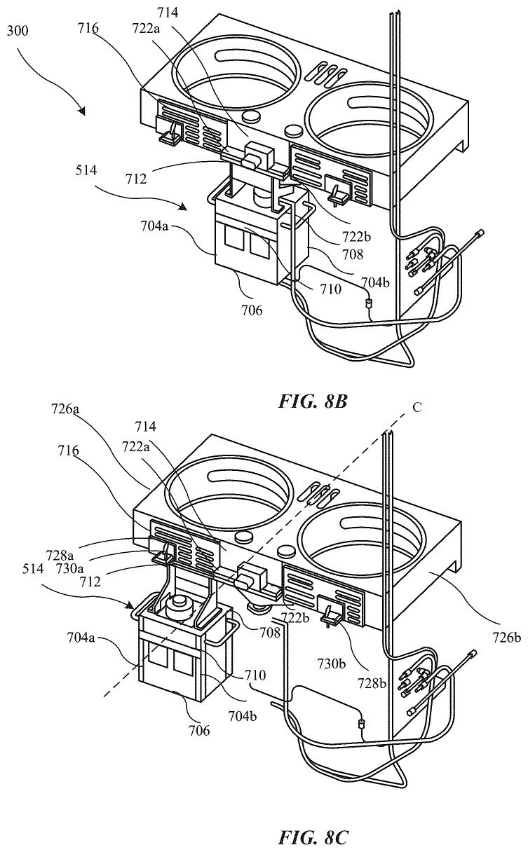

Nonetheless, support frame 702 may be supported by a mounting bar 712 fixedly or releasably attached to mounting plate 714. In embodiments, mounting bar may be fixedly or releasably attached to support arms 711, which may extend from upper support 708 to mounting bar 712, and may therefore firmly support the support frame 702 against mounting plate 714. Mounting plate 714 may be removably or permanently affixed to a side 716 of chamber 300, such as a lateral side disposed between an opposed upper surface 713 and lower surface 715 of chamber 300, in embodiments. In embodiments, the mounting plate 714 may be generally located along a central axis of chamber 300, as shown more clearly in FIGS. 8A-8C. The mounting plate may allow the force of the cleaning gas source 514 to be distributed, allowing the mounting assembly 700 to provide a stable base for cleaning gas source 514.

In embodiments, the support frame 702 may also include one or more tension components 718. In embodiments, the tension component 718 may be a spring or similar component that allows for some expansion of the frame while maintaining proper support. In the illustrated embodiment, the tension component 718 may include one or more springs which are initially tensioned by an attachment piece 720, such as a threaded screw. By utilizing such a combination, the tension component may be applied with a proper initial tension, allowing for a strong balance between support and flexibility during processing conditions. Namely, it is common for remote plasma sources, such as the inlet 601 and/or splitter 602, to expand during plasma generation due to thermal expansion. Thus, the design of the present technology allows the load to be transferred to mounting plate 714 while also accounting for thermal expansion during processing. In such embodiments, bottom support 706 may include a first plate 706a and a second plate 706b. first plate 706a may be attached to opposed sides 704a, 704b of the support farm 702 as discussed above, while second plate 706b may be supported via first plate 706a and one or more tension components 718.

In embodiments, mounting bar 712 may be releasably affixed to mounting plate 714 via one or more translatable attachments 722a, 722b extending through attachment housing 721a, 721b. Referring to FIGS. 8A-8C, by utilizing one or more translatable attachments 722, the cleaning gas source 514 may be translated to the left or right as illustrated by arrows 724. For instance, by removing first translatable attachment 722a (FIG. 7), the entire cleaning gas source 514 may be translated as illustrated by arrow 724b around second translatable attachment 722b. Similarly, by removing second translatable attachment 722b, the entire cleaning gas source 514 may be translated as illustrated by arrow 724a around first translatable attachment 722a. Namely, the remaining translatable attachment (e.g. non-removed attachment) may serve as an axis of rotation of which the cleaning RPS may rotate around and outward from side surface 716 of cleaning gas source 514. In such a manner, the cleaning RPS may be moved from a central location to a secondary side location, allowing for access to one or more chambers adjacent to the removed translatable attachment. In embodiments, the translatable attachment 722 may be a screw, bar, rivet, or the like, as known in the art.

For instance, FIGS. 8B and 8C, illustrate an embodiment where second translatable attachment 722b is removed from the structure shown in FIG. 8B. After removal of translatable attachment 722b, cleaning gas source 514 may be translated from a first central position to a secondary position. As illustrated, in embodiments, the secondary position may be located at a position between a central axis C of chamber 300 and an outer edge 726a, 726b of chamber 300. In embodiments, chamber 300 may include one or more secondary mounting plates 728a, 728b. When utilized, the one or more secondary mounting plates 728a, 728b may include a secondary mounting pin 730a, 730b. The mounting pins may be shaped and sized so as to correspond to the housing 721a, 721b vacated by the removed translatable attachment (such as through a screw hole or the like), and retain the cleaning gas source 514 in the secondary location. In embodiments, the cleaning gas source 514 may be retained in the second position during a cleaning or service operation.

Nonetheless, after the access to the desired chamber portion is complete, the secondary mounting pin 730a may be released. By releasing the secondary mounting pin, the cleaning gas source 514 may be rotated around first translatable attachment 722a, toward the central location, and re-affixed to second translatable attachment 722b. Moreover, referring to FIG. 8A, it should be understood that the cleaning gas source 514 may be translated towards a first side 726a or a second side 726b, based upon the translatable attachment removed.

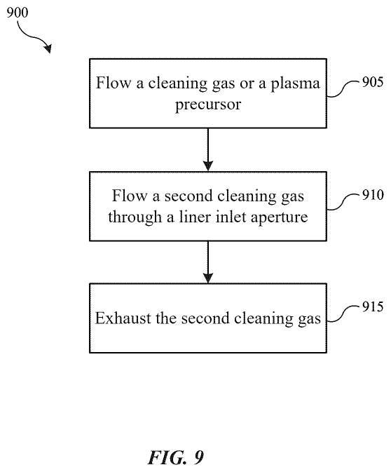

FIG. 9 shows operations of an exemplary method 900 of substrate processing according to some embodiments of the present technology. The method may be performed in a variety of processing chambers, including processing systems and chambers 100, 200, and 300 described above, which may include the cleaning RPS and pumping liner discussed above. Method 900 may include a number of optional operations, which may or may not be specifically associated with some embodiments of methods according to the present technology.

Method 900 may include a method that may include optional operations prior to initiation of method 900, or the method may include additional operations. For example, method 900 may include operations performed in different orders than illustrated. Nonetheless, in embodiments, method 900 may include an operation 905 of flowing a cleaning gas or a plasma precursor into a processing chamber. In embodiments, the processing chamber may be any chamber discussed in regards to the processing systems above. The method may include optionally evacuating the cleaning gas or plasma precursor from the chamber prior to flowing the second cleaning gas at operation 910, or may include flowing the second gas simultaneously with operation 905.

Nonetheless, in embodiments, operation 910 may be conducted by a secondary cleaning gas source. As discussed above, the secondary cleaning gas source may be fluidly coupled with an inlet aperture of a chamber liner. The inlet aperture may be advantageously located below a faceplate or processing region of the chamber. Thus, the cleaning gas from the secondary cleaning gas source may be flowed directly from the cleaning gas source through the inlet aperture, and around the liner. Furthermore, the cleaning gas from the secondary cleaning gas source may be exhausted at operation 915 without requiring the cleaning gas to traverse through one or more faceplate apertures. By providing the secondary cleaning gas source and inlet aperture according to the present technology, increased cleaning of components downstream of a faceplate may be exhibited. Moreover, in embodiments, such as system and process may allow for fewer deposits to be formed, alone or in conjunction with requiring smaller cleaning gas volumes, as the process may be run concurrently with a cleaning or deposition operation due at least in part to the location of the secondary cleaning gas source and inlet aperture(s). In embodiments, the present technology may be well suited for removing or combining with one or more carbon containing compounds, such as one or more carbon containing compounds formed or utilized during a CVD process, as an example only.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A substrate processing system, comprising:
a chamber body that defines a processing region;
a liner positioned within the chamber body defining a liner volume;
a faceplate positioned atop the liner;
a substrate support disposed within the chamber body, and
a cleaning gas source coupled with the liner volume through a cleaning gas plenum and one or more inlet apertures;
wherein at least one of the one or more inlet apertures is disposed in the processing region between the faceplate and a bottom wall of the chamber body.

2. The substrate processing system of claim 1, wherein:
the cleaning gas source is positioned vertically below the chamber body.

3. The substrate processing system of claim 1, wherein:
the one or more inlet apertures extend through a sidewall of the chamber body.

4. The substrate processing system of claim 3, wherein:
the liner comprises an exterior liner portion and an interior liner portion, wherein the liner volume is defined between the exterior liner portion and the interior liner portion.

5. The substrate processing system of claim 4, wherein:
the exterior liner portion extends around an interior perimeter of the chamber body.

6. The substrate processing system of claim 5, wherein:
the interior liner portion is laterally spaced apart in a direction towards the substrate support from the exterior liner portion.

7. The substrate processing system of claim 5, wherein:
the one or more inlet apertures extend through the exterior liner portion.

8. The substrate processing system of claim 3, wherein:
the one or more inlet apertures extend through the sidewall of the chamber body at a height that is about 10% to about 90% of a total height of the sidewall.

9. The substrate processing system of claim 4, further comprising an exhaust outlet, wherein the exhaust outlet is disposed within the liner volume.

10. A substrate processing system, comprising:
a chamber having a chamber body that defines a processing region;
a liner positioned with the chamber body defining a liner volume;
a faceplate positioned atop the liner;
a substrate support disposed within the chamber body,
a cleaning gas source disposed below the chamber body and coupled with the liner volume through one or more inlet apertures in the chamber body, wherein at least one of the one or more inlet apertures is disposed in the processing region; and
a support frame, wherein the cleaning gas source is seated on the support frame, wherein the support frame is pivotally mounted to a lateral side of the chamber body.

11. The substrate processing system of claim 10, wherein:
the support frame comprises a bottom surface having a first plate and a second plate, wherein one or more tension components support the second plate over the first plate.

12. The substrate processing system of claim 11, wherein:
at least one of the one or more tension components comprise a spring affixed to the first plate.

13. The substrate processing system of claim 10, wherein the substrate processing system comprises two or more chambers, wherein the cleaning gas source is fluidly coupled with each chamber of the two or more chambers.

14. The substrate processing system of claim 10, wherein:
the cleaning gas source comprises a processing position, wherein the cleaning gas source is disposed along a central axis of the chamber.

15. The substrate processing system of claim 14, wherein:
one or more secondary mounting plates affixed to a lateral side of the chamber body between the central axis of the chamber and a lateral edge of the chamber.

16. The substrate processing system of claim 15, further comprising:
the one or more secondary mounting plates are configured to receive the cleaning gas source in a second position.

17. A processing method, comprising:
flowing a cleaning gas or a plasma precursor into a processing region of a semiconductor processing chamber through a showerhead, the semiconductor processing chamber comprising
a liner positioned with processing region defining a liner volume, and
a cleaning gas source directly coupled with the liner volume through a cleaning gas plenum and one or more inlet apertures;
wherein at least one of the one or more inlet apertures is disposed in the processing region;
flowing a second cleaning gas through the one or more inlet apertures; and
exhausting the second cleaning gas through the liner volume.

18. The processing method of claim 17, wherein:
the cleaning gas is flowed into the processing region, wherein the second cleaning gas is flowed into the semiconductor processing chamber simultaneously with the cleaning gas.

19. The processing method of claim 17, wherein:
the plasma precursor is flowed into the processing region, wherein the second cleaning gas is flowed into the semiconductor processing chamber simultaneously with the plasma precursor.

20. The processing method of claim 19, wherein the plasma precursor comprises a carbon containing precursor.
